(19) United States
(12) Patent Application Publication
(10) Pub. No.: US 2003/0214358 A1
(43) Pub. Date: Nov. 20, 2003

(54) Multistage amplifier circuit capable of boosting output power

(75) Inventor: Kazuya Yamamoto, Hyogo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 10/303,954

(22) Filed: Nov. 26, 2002

(30) Foreign Application Priority Data
May 17, 2002 (JP) 2002-142742(P)

(51) Int. Cl. H03F 3/68

(52) U.S. Cl. 330/310

(57) ABSTRACT

A drain current flowing through a first transistor in a multistage amplifier circuit and a drain current flowing through a second transistor may have different current values from each other by a current regulator circuit. As a result, the amplifying operation of the second transistor may not be saturated even when the output power of the first transistor is increased. Accordingly, the circuit can operate with low current consumption and improve the output power.

### BACKGROUND OF THE INVENTION

1. Field of the Invention

The present invention relates to a multistage amplifier circuit, and more specifically, to a multistage amplifier circuit including a current regulator circuit.

2. Description of the Background Art

Two-stage amplifier circuits are the small signal amplifier circuits handling a voltage and a current of small amplitude. Among the two-stage amplifier circuits, a circuit referred to as a current reusing circuit shares a current between two transistors in the amplifier circuit. Therefore, the current reusing circuit achieves high gain while operating with small current consumption.

FIG. 6 is a circuit diagram showing a configuration of a CMOS low noise amplifier circuit for radio communications that functions as a conventional current reusing circuit.

Referring to FIG. 6, a CMOS low noise amplifier circuit 10 includes N-channel MOS transistors QN1 and QN2, inductors L1 to L4 formed with spiral inductors or the like, capacitors C1 to C3 and Cd1 to Cd4, resistance elements Rd and Rg, an input terminal 1 and an output terminal 2.

The inductor L1 is connected between the input terminal 1 and the gate of the transistor QN1. The capacitor C1 has one terminal connected between the input terminal 1 and the inductor L1, and has the other terminal connected to a ground node 20.

The resistance element Rg has one terminal connected to the gate of the transistor QN1, and has the other terminal connected to a node N1 applied with a prescribed voltage Vg1. The capacitor Cd1 is connected between the node N1 and the ground node 20.

The transistor QN1 has its source connected to the ground node 20. The transistor QN1 has its drain connected to the source of the transistor QN2 through the inductor L2 and also connected to the gate of the transistor QN2 through a capacitor C2.

The inductor L3 is connected between a node N2 applied with a prescribed voltage Vg2 and the gate of the transistor QN2. The capacitor Cd3 is connected between the node N2 and the ground node 20.

The source of the transistor QN2 is connected to the ground node 20 through the capacitor Cd2.

The resistance element Rd has one terminal connected to the drain of the transistor QN2. Its other terminal is connected to the output terminal 2 through the capacitor C3. Here, the resistance element Rd is a drain resistance loaded to stabilize the circuit 10. Hence, the resistance element Rd may be omitted depending on the circuit constant and operating frequency.

The inductor L4 has its one terminal connected to the node N4 applied with a prescribed voltage Vdd, and its other terminal connected between the resistance element Rd and the capacitor C3. The capacitor Cd4 is connected between the node N4 and the ground node 20.

Here, the prescribed voltage Vg1 is the gate bias voltage of the transistor QN1, while the prescribed voltage Vg2 is the gate bias voltage of the transistor QN2. The prescribed voltage Vdd is the drain voltage of the transistor QN2.

In FIG. 6, the inductor L1 and the capacitor C1 constitute an input matching circuit. The inductor L3 and the capacitor C2 constitute an interstage matching circuit. The inductor L4 and the capacitor C3 constitute an output matching circuit.

In FIG. 6, the capacitors Cd1 to Cd4 function as decoupling capacitors. In other words, the capacitors Cd1 to Cd4 utilize charge and discharge function thereof to absorb noise (voltage fluctuation) on the power supply line. The capacitors Cd1 to Cd4 provide sufficiently low impedance at the operating frequency.

In the CMOS low noise amplifier circuit 10 shown in FIG. 6, the inductor L2 is set to provide sufficiently high impedance at the operating frequency. At this time, the radio frequency (hereinafter referred to as “RF”) signal input from the input terminal 1 is amplified by the transistor QN1 to be transmitted to the gate of the transistor QN2. At this time, the transistors QN1 and QN2 share the drain current Id. Hence, the CMOS low noise amplifier circuit 10 can operate with small current consumption despite of being a two-stage amplifier circuit having its source grounded.

On the other hand, when using the CMOS low noise amplifier circuit 10 as a power amplifier circuit and not as a small signal amplifier circuit, a problem arises in the output power characteristics thereof.

FIG. 7 is a schematic graph showing the input and output characteristics of the CMOS low noise amplifier circuit 10 shown in FIG. 6. In FIG. 7, input on abscissa indicates the power of the signal IN of FIG. 6 (unit: dBm), while the output on ordinate indicates the power of the signal OUT of FIG. 6 (unit: dBm).

Referring to FIG. 7, in the CMOS low noise amplifier circuit 10, when the input level increases, the output level increases in proportion thereto.

Note that the drain current Id is shared by the transistors QN1 and QN2 in the CMOS low noise amplifier circuit 10. Hence, when input power is more than Pi0 and the output power of the transistor QN1 is increased, the amplifying operation of the transistor QN2 is saturated. As a result, the output power of the CMOS low noise amplifier circuit 10 can not be increased in proportion to the input power.

### SUMMARY OF THE INVENTION

Therefore, the object of the present invention is to provide a multistage amplifier circuit which can operate with low current consumption and improve output power.

The multistage amplifier circuit according to the present invention includes a first transistor, a second transistor and a resistance element. The first transistor has first and second terminals. The first terminal receives an input signal. The second terminal outputs the input signal after amplification.

The second transistor includes third, fourth, and fifth terminals. The third terminal is electrically connected to the second terminal of the first transistor. The fourth terminal outputs amplified signal which has been received on the third terminal. The fifth terminal is electrically connected to the second terminal of the first transistor.

The resistance element has two terminals and one of which is electrically connected to the fifth terminal of the second transistor to pass the current therebetween.

Thus, the multistage amplifier circuit according to the present invention can suppress saturation of the amplifying operation of the second transistor even when the output voltage of the first transistor is increased.

Additionally, the multistage amplifier circuit according to the present invention includes first, second and third transistors. The first transistor has first and second terminals. The first terminal receives an input signal. The second terminal output the input signal after amplification.

The second transistor has third, fourth and fifth terminals. The third terminal is electrically connected to the second terminal of the first transistor. The fourth terminal outputs the signal which has been received at the third terminal and being amplified. The fifth terminal is electrically connected to the second terminal of the first transistor.

The third transistor has two terminals and one of which is electrically connected to the fifth terminal of the second transistor to pass the current therebetween.

Thus, the multistage amplifier circuit according to the present invention can suppress saturation of the amplifying operation of the second transistor even when the output voltage of the first transistor is increased.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a circuit diagram showing a configuration of a multistage amplifier circuit according to a first embodiment of the present invention;

FIG. 2 is a schematic graph showing the input and output characteristics according to the first embodiment of the present invention;

FIG. 3 is a circuit diagram showing a configuration of a multistage amplifier circuit according to a second embodiment of the present invention;

FIG. 4 is a circuit diagram showing another configuration of a multistage amplifier circuit according to the second embodiment of the present invention;

FIG. 5 is a circuit diagram related to an operation in which the multistage amplifier circuit shown in FIG. 1 is applied as a multiplier;

FIG. 6 is a circuit diagram showing a configuration of a CMOS low noise amplifier circuit for radio communications which function as a conventional current reusing circuit; and

FIG. 7 is a schematic graph showing input and output characteristics of the CMOS low noise amplifier circuit shown in FIG. 6.

### DESCRIPTION OF THE PREFERRED EMBODIMENTS

In the following, embodiments of the present invention will be described in detail referring to the figures. Similar or corresponding elements are given similar reference characters throughout the figures and descriptions thereof will not be repeated.

(First Embodiment)

FIG. 1 is a circuit diagram showing a configuration of a multistage amplifier circuit according to a first embodiment of the present invention.

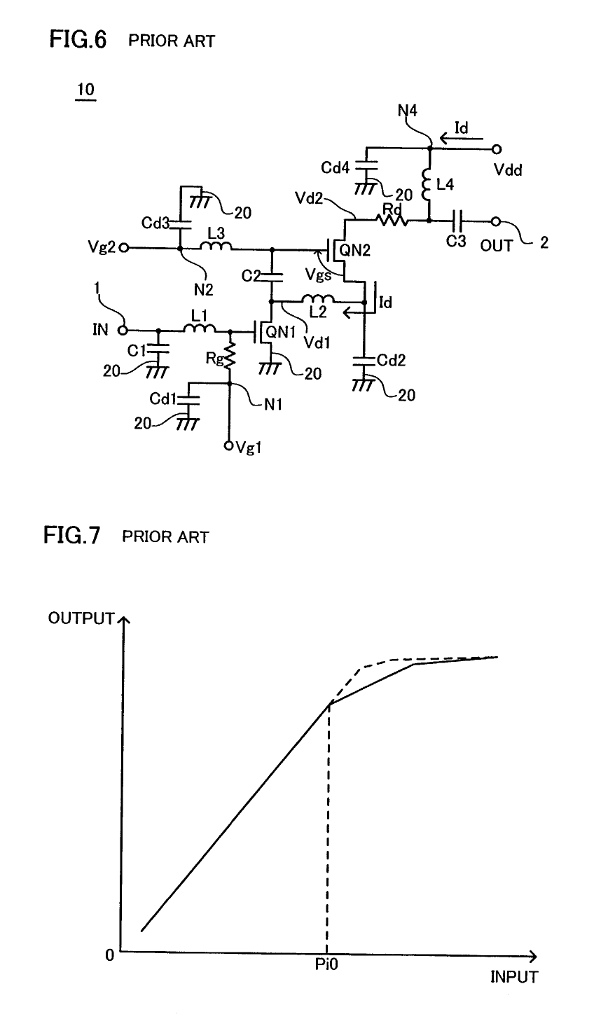

Referring to FIG. 1, compared to the CMOS low noise amplifier circuit 10 shown in FIG. 6, multistage amplifier circuit 50 is additionally provided with a current regulator circuit 60.

The current regulator circuit 60 is connected between the source of the transistor QN2 and the ground node 20. The current regulator circuit 60 includes a resistance element Rs0. A resistance element Rs0 has its one terminal connected to the source of the transistor QN2 and has its other terminal connected to the ground node 20.

Other circuit configuration is similar to those of the CMOS low noise amplifier circuit 10 shown in FIG. 6, thus the descriptions thereof will not be repeated.

The operation of the multistage amplifier circuit 50 having above circuit configuration will be described.

The currents Is0, Id1, and Id2 in the current regulator circuit 60 are DC current. In other words, the currents Is0, Id1 and Id2 are direct average current averaged by time (i.e., average current determined by integrating current with time period from a certain time point t1 to the other time point t2 and then dividing the integrated value by time (t2−t1)) (same in the following).

Here, the currents Is0, Id1 and Id2 satisfy the following relationship: Id2=Id1+Is0

More specifically, resistance element Rs0 regulates current distribution to the transistors QN1 and QN2. Thus, currents respectively flowing into the transistors QN1 and QN2 can be made different from each other. As a result, saturation of the amplifying operation of the transistor QN2 can be suppressed even when the output voltage of the transistor QN1 is increased.

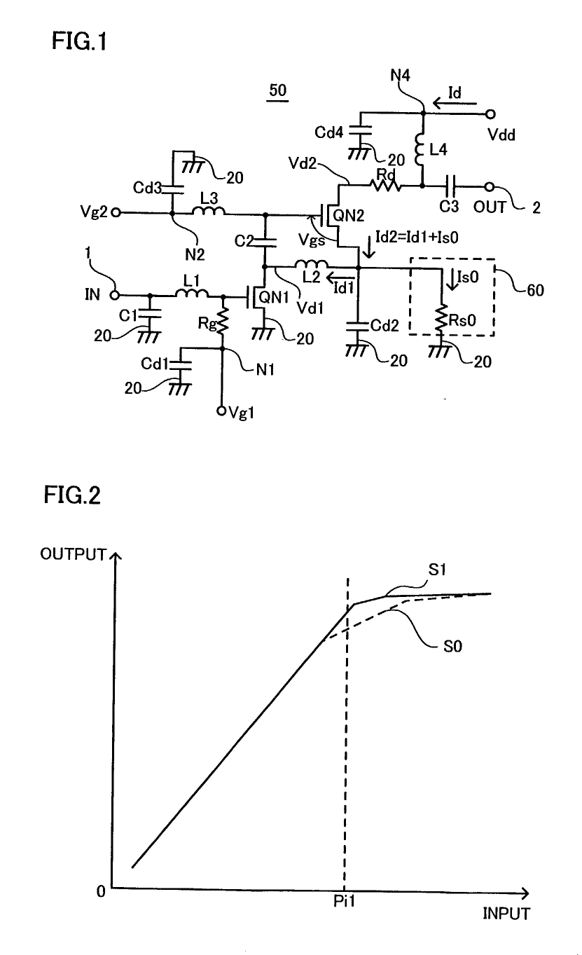

FIG. 2 schematically shows the input and output characteristics according to the first embodiment of the present invention. In FIG. 2, input on abscissa indicates the power of the signal IN of FIG. 1 (unit: dBm), while the output on ordinate indicates the power of the signal OUT of FIG. 1 (unit: dBm).

Referring to FIG. 2, input and output characteristics of the conventional CMOS low noise amplifier circuit 10 is indicated by the curve S0, while input and output characteristics of the multistage amplifier circuit 50 according to the first embodiment of the present invention is indicated by the curve S1.

When the input power is Pi1, the output power of the transistor QN1 in the conventional CMOS low noise amplifier circuit 10 increases, and drain currents flowing through the transistors QN1 and QN2 are equal. Hence, the amplifying operation of the transistor QN2 is saturated. As a result, the output power of the CMOS low noise amplifier circuit 10 can not be increased in proportion to its input power.

When the input power is Pi1, the drain current Id1 flowing through the transistor QN1 in the multistage amplifier circuit 50 is made smaller than the drain current Id2 flowing through the transistor QN2 by the current regulator circuit 60. Hence, the amplifying operation of the transistor QN2 may not be saturated even when the output power of the transistor QN1 is increased. As a result, the output power of the multistage amplifier circuit 50 becomes higher than that of the COMS low noise amplifier circuit 10.

The multistage amplifier circuit according to the first embodiment, having transistors adjacent to each other therein, can be regulated by the above operation so that amplifying operation of the rear stage transistor may not be saturated even when the output power of the front stage transistor is increased. Hence, the output power characteristics thereof can be improved. Additionally, chip size of the multistage amplifier circuit hardly increases since the current regulator circuit can be implemented with the resistance element.

Though in the multistage amplifier circuit 50 according to the first embodiment the N-channel MOS transistor is employed, a bipolar transistor may alternatively be employed. Additionally, a GaAs MESFET (Metal Semiconductor Field-Effect Transistor) may alternatively be employed as well.

(Second Embodiment)

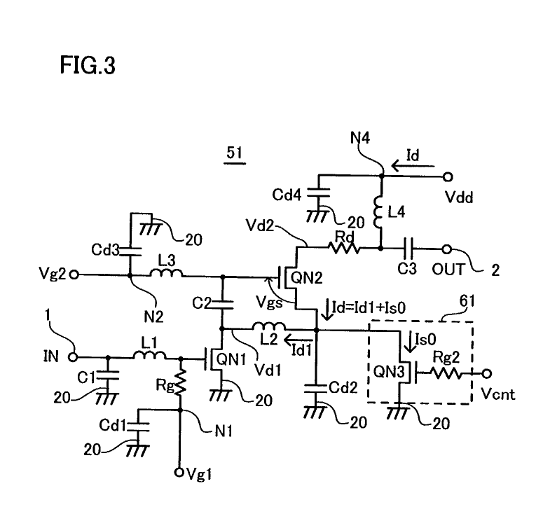

FIG. 3 is a circuit diagram showing a configuration of a multistage amplifier circuit according to a second embodiment of the present invention.

Compared to FIG. 1, the multistage amplifier circuit 51 is provided with a current regulator circuit 61 in place of the current regulator circuit 60.

The current regulator circuit 61 includes an N-channel MOS transistor QN3 and a resistance element Rg2.

The transistor QN3 is connected between the source of the transistor QN2 and the ground node 20. The resistance element Rg2 is connected between the gate of the transistor QN3 and the node N5. The node N5 is supplied with a gate control voltage Vcnt.

Since other circuit configuration is similar to the one shown in FIG. 1, descriptions thereof will not be repeated.

The operation of the multistage amplifier circuit 51 configured as above will be described.

Since the current regulator circuit 61 includes the transistor QN3, it functions as a variable resistor. More specifically, the drain current Is0 flowing through the transistor QN3 can be regulated by the gate control voltage Vcnt applied to the node N5. Hence, distribution of the drain current Id1 flowing through the transistor QN1 and the drain current Id2 flowing through the transistor QN2 can be regulated in the following range: 0≦Id1≦Id2

Thus, the operation similar to that of the multistage amplifier circuit 50 according to the first embodiment can be realized.

Further, the gate control voltage Vcnt may be regulated so that the potential of the transistor QN2 becomes approximately 0V. Here, the drain current Id1 does not flow through the transistor QN1. Thus, the multistage amplifier circuit 51 can also stop the amplifying operation of the transistor QN1. Additionally, the multistage amplifier circuit 51 according to the second embodiment of the present invention can be implemented by simply adding the transistor and the resistance element to the conventional CMOS low noise amplifier circuit 10. Accordingly, chip size thereof hardly increases.

Though the N-channel MOS transistor is employed in the multistage amplifier circuit 51 according to the second embodiment, a bipolar transistor may alternatively be employed. Additionally, a GaAs MESFET may alternatively be employed as well.

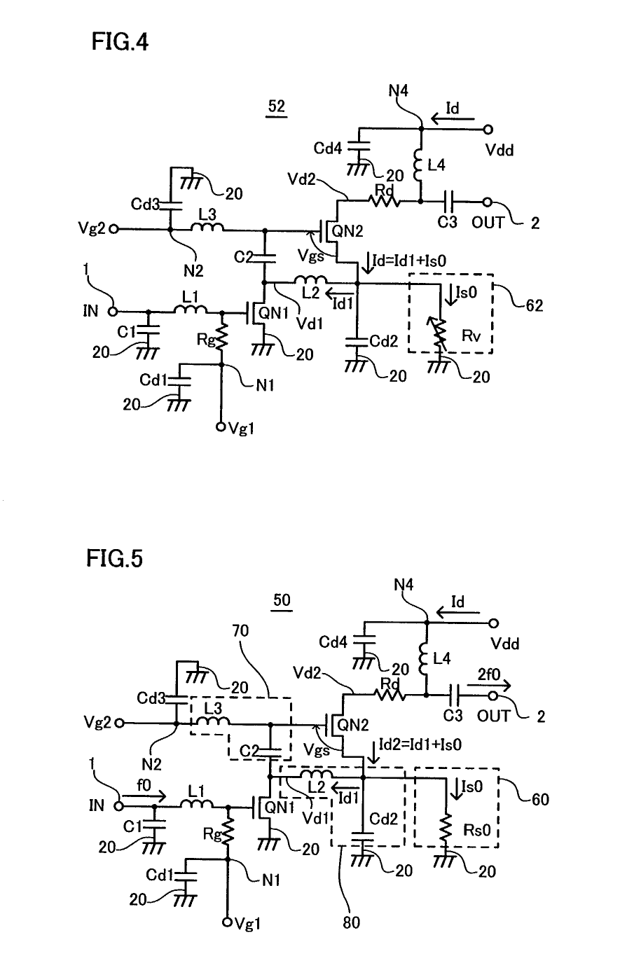

Further, as shown in FIG. 4, a multistage regulator circuit 52 provided with a current regulator circuit 62 including a variable resistance element Rv in place of the current regulator circuit 61 can realize similar operation as the multistage amplifier circuit 51 by adjusting the variable resistance element Rv.

(Third Embodiment)

The multistage amplifier circuit 50 shown in FIG. 1 can also be applied as a multiplier.

FIG. 5 is a circuit diagram related to the operation of the multistage amplifier circuit as applied as a multiplier.

Referring to FIG. 5, the circuit configuration thereof is similar to that of FIG. 1, and therefore its description will not be repeated.

A frequency transmit circuit 70 includes an inductor L3 and a capacitor C2. A frequency shorting circuit 80 includes an inductor L2 and a capacitor Cd2. The frequency transmit circuit 70 transmits a signal with particular frequency among all signals output from the transistor QN1 to the gate of the transistor QN2. In other words, the frequency transmit circuit 70 functions as a band pass filter. The frequency shorting circuit 80 is used to short-circuit a signal of a prescribed frequency band to the ground node 20.

In the multistage amplifier circuit 50 with above configuration, an operation will be described in which a FR signal is input at frequency f0 and is output at 2fO, being amplified.

The RF signal is input from the input terminal 1. At this time, the inductor L1 and capacitor C1 functioning as an input matching circuit is matched at the frequency f0. Thus, the RF signal at the frequency f0 is input to the gate of the transistor QN1.

At this time, the gate bias voltage Vg1 is a pinch-off voltage. Here, the input power to the transistor QN1 is distorted under the non-linear effect. As a result, the transistor QN1 outputs RF signal at frequency f0 and, in addition, a plurality of harmonics which are signals at, for example, frequency f2.

At this time, the inductor L2 and the capacitor Cd2 are set so that the frequency shorting circuit 80 provides, between the drain of the transistor QN1 and the ground node 20 for the RF signal at frequency f0, an impedance smaller than for the RF signal at frequency 2f0. Further, when the frequency transmit circuit 70 transmits the RF signal output from the transistor QN1 to the gate of the transistor QN2, the inductor L3 and the capacitor C2 are set so that the power of the RF signal at frequency f0 is lost more upon transmission than at frequency 2f0.

As a result, among a plurality of signals output from the transistor QN1, only the RF signal at frequency 2f0 is input to the gate of the transistor QN2. Hence, the transistor QN2 amplifies only the RF signal at frequency 2f0. Thus, the multistage amplifier circuit 50 also functions as a multiplier.

When the multistage amplifier circuit 50 is not provided with the current regulator circuit 60, the drain current Id2 flowing through the transistor QN2 and the drain current Id1 flowing through the transistor QN1 are at equal value. Hence, when operating the multistage amplifier circuit 50 without the current regulator circuit 60 as a multiplier, the pinch-off voltage is input to the gate of the transistor QN1 and thus the drain current Id1 is hardly passed and becomes very weak. Correspondingly, the drain current Id2 flowing through the transistor QN2 becomes very weak. Accordingly, the amplifying operation by the transistor QN2 is hindered.

With the current regulator circuit 60, however, the drain currents Id1 and Id2 may have different current value from each other. Thus, the transistor QN2 can achieve amplifying operation even when the multistage amplifier circuit 50 functions as a multiplier. Further, by regulation of the current regulator circuit 60, part of the drain current Id2 of the transistor QN2 can be reused as the drain current Id1 of the transistor QN1, and thus the current Is0 is minimized. As a result, the multistage amplifier circuit 50 functions as a multiplier which operates with low current consumption.

Though the N-channel MOS transistor is employed in the multistage amplifier circuit 51 according to the third embodiment, a bipolar transistor may alternatively be employed. Additionally, a GaAs MESFET may alternatively be employed as well.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A multistage amplifier circuit, comprising:
a first transistor having a first terminal for receiving an input signal and a second terminal for outputting said input signal after amplification;
a second transistor having a third terminal electrically connected to said second terminal of said first transistor, a fourth terminal for outputting said signal being received at said third terminal and being amplified and a fifth terminal electrically connected to said second terminal of said first transistor; and
a resistance element having two terminals one of which is electrically connected to said fifth terminal of the second transistor to pass a current therebetween.

2. The multistage amplifier circuit according to claim 1, further comprising:
a frequency transmit circuit connected to said second terminal of said first transistor and said third terminal of said second transistor for transmitting particular frequency component among a plurality of frequency components included in a signal output from said first transistor; and
a frequency shorting circuit connected to said second terminal of said first transistor and a ground node for reducing the impedance between said second terminal and said ground node for a frequency component different from said particular frequency component among a plurality of frequency components compared to that for the particular frequency component.

3. The multistage amplifier circuit according to claim 1, wherein
at least a capacitor is connected between said second terminal of said first transistor and said third terminal of said second transistor, and at least an inductor is connected between said second terminal of said first transistor and said fifth terminal of said second transistor.

4. A multistage amplifier circuit, comprising:
a first transistor having a first terminal for receiving an input signal and a second terminal for outputting said input signal after amplification;
a second transistor having a third terminal electrically connected to said second terminal of said first transistor, a fourth terminal for outputting said signal being received at said third terminal and being amplified and a fifth terminal electrically connected to said second terminal of said first transistor; and
a third transistor having two terminals one of which is electrically connected to said fifth terminal of said second transistor to pass a current therebetween.

5. The multistage amplifier circuit according to claim 4, further comprising:
a frequency transmit circuit connected to said second terminal of said first transistor and said third terminal of said second transistor for transmitting particular frequency component among a plurality of frequency components included in a signal output from said first transistor; and
a frequency shorting circuit connected to said second terminal of said first transistor and a ground node for reducing the impedance between said second terminal and said ground node for a frequency component different from said particular frequency component among a plurality of frequency components compared to that for the particular frequency component.

6. The multistage amplifier circuit according to claim 4, wherein
at least a capacitor is connected between said second terminal of said first transistor and said third terminal of said second transistor, and at least an inductor is connected between said second terminal of said first transistor and said fifth terminal of said second transistor.
